(19) United States
(12) Patent Application Publication
(10) Pub. No.: US 2025/0189041 A1
(43) Pub. Date: Jun. 12, 2025

(54) BREATHER ASSEMBLY WITH CONDUCTIVE SHIELD

(71) Applicant: Donaldson Company, Inc., Bloomington, MN (US)

(72) Inventors: Daniel J. Dotzler, Webster, MN (US); Robert O. Nelson, Eagan, MN (US); Matthew P. Brownson, Stillwater, MN (US); Matthew J. Goode, Blaine, MN (US)

(21) Appl. No.: 18/970,532

(22) Filed: Dec. 5, 2024

Related U.S. Application Data
(60) Provisional application No. 63/627,934, filed on Feb. 1, 2024.
(60) Provisional application No. 63/606,968, filed on Dec. 6, 2023.

(51) Int. Cl. F16K 1/32

(52) U.S. Cl. CPC F16K 1/32

(57) ABSTRACT

The present technology relates to a breather assembly. The breather assembly has an assembly body having a coupling structure configured to be coupled to a housing, an assembly opening, and an environmental opening. The assembly body is configured to define an airflow pathway between the assembly opening and an outside environment through the environmental opening. A conductive shield is coupled to the assembly body and disposed across the assembly opening. The conductive shield defines a portion of the airflow pathway. The conductive shield is configured to be in conductive communication with the housing in response to the coupling structure being coupled to the housing.

### PRIORITY

This application claims priority to U.S. Provisional App. No. 63/627,934 filed on 1 Feb. 2024 and U.S. Provisional App. No. 63/606,968 filed on 6 Dec. 2023, the disclosures of which are incorporated by reference in their entireties.

### TECHNOLOGICAL FIELD

The present technology relates to a breather assembly. More particularly, the present technology relates to a breather assembly with the conductive shield.

### SUMMARY

Some embodiments of the technology disclosed herein relate to a breather assembly. The breather assembly has an assembly body having a coupling structure configured to be coupled to a housing, an assembly opening, and an environmental opening. The assembly body is configured to define an airflow pathway between the assembly opening and an outside environment through the environmental opening. A conductive shield is coupled to the assembly body and disposed across the assembly opening. The conductive shield defines a portion of the airflow pathway. The conductive shield is configured to be in conductive communication with the housing in response to the coupling structure being coupled to the housing.

In some such embodiments, the assembly body is constructed of plastic. Additionally or alternatively, the coupling structure includes a bayonet connector. Additionally or alternatively, the bayonet connector is defined by the assembly body. Additionally or alternatively, the bayonet connector is defined by the conductive shield.

Additionally or alternatively, the conductive shield and the bayonet connector define an interference fit. Additionally or alternatively, the bayonet connector defines a plurality of partial circumferential channels each having an open end and a closed end. The open end and the closed end are separated by an axially extending retaining ridge. Additionally or alternatively, the plurality of partial circumferential channels are circumferentially aligned. Additionally or alternatively, the open end is tapered axially inward towards the closed end. Additionally or alternatively, the conductive shield includes a plurality of radially extending tabs, and each radially extending tab is received by a closed end. Additionally or alternatively, each of the plurality of partial circumferential channels define a circumferential clearance from an adjacent channel that is sized to receive one of the plurality of radially extending tabs. Additionally or alternatively, each radially extending tab has a thickness that is less than an axial height of the closed end. Additionally or alternatively, the conductive shield is stainless steel. Additionally or alternatively, a valve is disposed in the assembly body, where the valve selectively obstructs the airflow pathway between the assembly opening and the environmental opening. Additionally or alternatively, the conductive shield defines a plurality of openings across the airflow pathway.

Some embodiments of the technology disclosed herein relate to a method of making a breather assembly. An assembly body is formed, having a coupling structure configured to be coupled to a housing. The assembly body has an assembly opening, and an environmental opening. The assembly body is configured to define an airflow pathway between the assembly opening and an outside environment through the environmental opening. A conductive shield is coupled to the assembly body across the assembly opening. The conductive shield defines a portion of the airflow pathway. The conductive shield is configured to be in conductive communication with the housing when the coupling structure is coupled to the housing.

In some such embodiments, the assembly body is constructed of plastic. Additionally or alternatively, the coupling structure includes a bayonet connector. Additionally or alternatively, the bayonet connector is defined by the assembly body. Additionally or alternatively, the bayonet connector is defined by the conductive shield. Additionally or alternatively, the conductive shield and the bayonet connector define an interference fit. Additionally or alternatively, coupling the conductive shield to the bayonet connector includes inserting each of a plurality of radially extending tabs defined by the conductive shield between each of a plurality of partial circumferential channels defined by the bayonet connector. Coupling the conductive shield to the bayonet connector includes rotating the conductive shield relative to the bayonet connector to translate each radially extending tab from an open end of a corresponding partial circumferential channel to a closed end of the corresponding partial circumferential channel, where the open end and the closed end are separated by an axially extending retaining ridge.

Additionally or alternatively, the plurality of partial circumferential channels are circumferentially aligned. Additionally or alternatively, the open end is tapered axially inward towards the closed end. Additionally or alternatively, each radially extending tab has a thickness that is less than an axial height of the closed end. Additionally or alternatively, the conductive shield is stainless steel. Additionally or alternatively, a valve is coupled to the assembly body to selectively obstruct the airflow pathway between the assembly opening and the environmental opening. Additionally or alternatively, the conductive shield defines a plurality of openings across the airflow pathway.

### BRIEF DESCRIPTION OF THE DRAWINGS

The present technology may be more completely understood and appreciated in consideration of the following detailed description of various embodiments in connection with the accompanying drawings.

FIG. 1 depicts a first perspective view of a portion of an example system consistent with the present technology.

FIG. 2 is a second perspective view of a portion of an example system consistent with embodiments.

FIG. 3 perspective view of an example assembly consistent with FIGS. 1 and 2 in an unassembled state.

FIG. 4 is a perspective view of an example assembly consistent with FIG. 3 in an assembled state.

FIG. 5 is an exploded view of an example assembly consistent with the present technology.

FIG. 6 is a cross-sectional perspective view of the example assembly of FIG. 5.

FIG. 7 is a perspective view of another example assembly consistent with the present technology.

FIG. 8 is a cross-sectional perspective view of an example assembly consistent with FIG. 7.

FIG. 9 is a perspective view of yet another example assembly consistent with the technology disclosed herein.

The figures are rendered primarily for clarity and, as a result, are not necessarily drawn to scale. Moreover, various structure/components, including but not limited to fasteners, electrical components (wiring, cables, etc.), and the like, may be shown diagrammatically or removed from some or all of the views to better illustrate aspects of the depicted embodiments, or where inclusion of such structure/components is not necessary to an understanding of the various exemplary embodiments described herein. The lack of illustration/description of such structure/components in a particular figure is, however, not to be interpreted as limiting the scope of the various embodiments in any way.

### DETAILED DESCRIPTION

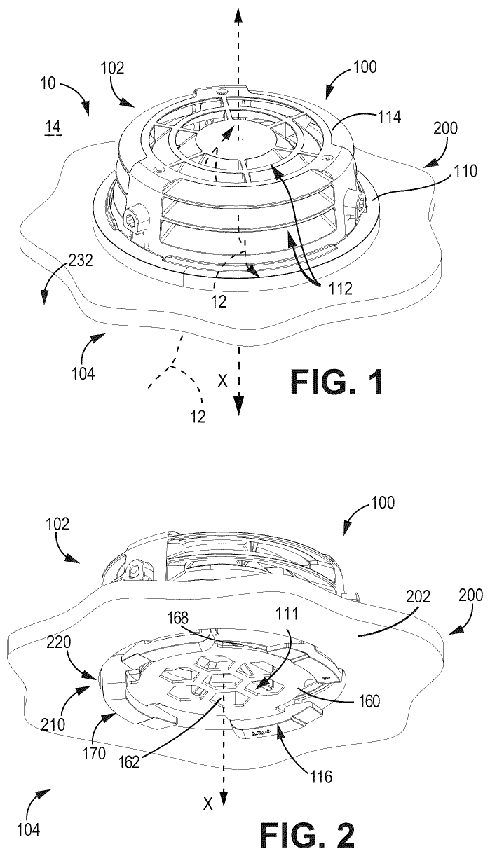

FIGS. 1 and 2 depict different perspective views of an example system 10 having a housing 200 and a breather assembly 100. FIG. 4 depicts a perspective view of the breather assembly 100 without the housing. The housing 200 can be consistent with a variety of different types of housings known in the art. The housing 200 is generally constructed of a conductive material. In some specific implementations, the housing is a battery housing. The housing 200 generally defines an interior 232.

The breather assembly 100 is generally configured to be coupled to the housing 200. The breather assembly 100 has a first end 102 and a second end 104. The breather assembly 100 is generally configured to facilitate airflow between the housing 200 and the outside environment 14 when it is coupled to the housing. The breather assembly 100 has an assembly body 110. The breather assembly 100 has a coupling structure 116 configured to be coupled to the housing 200. The housing 200 that the breather assembly 100 is configured to be coupled to generally defines a housing opening 210 that is configured to receive the breather assembly 100. The housing 200 defines a mating structure 220 around the housing opening 210. The mating structure 220 is generally configured to mate with the coupling structure 116. In various embodiments the mating structure 220 is configured to sealably engage a breather assembly 100.

In the current example, the coupling structure 116 includes a bayonet connector. The bayonet connector is defined by the assembly body 110, although other configurations are possible, which will be discussed in more detail below. The mating structure 220 is a bayonet receptacle that is configured to be received by the bayonet connector. Other mating configurations are also possible. In various implementations that coupling structure 116 allows coupling of the breather assembly 100 to a housing 200 from the outside of the housing 200 without accessing the inside of the housing 200. In some other embodiments the coupling structure is a screw thread that is configured to be received by a mating screw thread defined by the housing around the housing opening. In some embodiments the coupling structure and the housing form a snap fit. In some embodiments the coupling structure is a contact surface that is configured to couple to a mating contact surface of the housing around the housing opening. In such examples, the coupling structure can be coupled to the housing through the use of fasteners, adhesives, welds, and the like.

As is particularly visible in FIG. 4, the coupling structure 116 includes a sealing surface 130 that is configured to form a seal between the breather assembly 100 and the housing 200 around the housing opening 210. In the current example, the sealing surface 130 is defined, at least in part, by a sealing ring 132 that is configured to be compressed between the breather assembly 100 and the housing 200 around the housing opening 210. The sealing surface 130 is configured to create a seal between the breather assembly 100 and the housing 200 when the breather assembly 100 is coupled to the housing 200. In embodiments consistent with the current example, the sealing surface 130 is defined around the bayonet connector. The sealing ring 132 can be an elastomeric material. In some embodiments the sealing ring 132 is rubber or another gasketing or sealing material. In some embodiments the sealing surface 130 includes an annular recess 134 that is configured to receive the sealing ring 132.

FIG. 9 depicts another breather assembly 400 consistent with various examples that particularly shows another sealing surface 430 design. In this example, the sealing surface 430 has a sealing ring 432 that is also configured to be compressed between the breather assembly 400 and a housing around a housing opening. The sealing ring 432 is disposed in an annular recess 434 defined by the assembly body 410 of the breather assembly 400. In the current example, the sealing ring 432 has at least one seal projection 438 extending outward from the rest of a main portion of the sealing ring 432 (such as the portion that forms a ring shape). The assembly body 410 defines one or more grooves 436 extending radially outward from the annular recess 434. Each groove 436 is configured to receive a corresponding seal projection 438. The groove 436 can be configured to frictionally receive a corresponding seal projection 438 in some examples. In various examples, the groove 436 is configured to extend through an outer lateral boundary of the assembly body 410 such that the corresponding seal projection 438 is visible from the outside of the breather assembly 400. In some embodiments, the sealing ring 432, and in particular the projection(s) 438, is a different color than the assembly body 410 such that the presence of the sealing ring 432 can be ascertained upon visual inspection.

In some implementations, the sealing surface 430 configuration may advantageously prevent shifting of the sealing ring 432 relative to the assembly body 410. In some implementations, the sealing surface 430 configuration may advantageously increase frictional forces to maintain the sealing ring 432 in the annular recess 434 by relatively increasing the surface area contact between the sealing ring and the assembly body 410 around the annular recess 434. In some implementations the sealing surface 430 configuration may advantageously allow a user to visually ascertain whether a sealing ring 432 is present between the assembly body 410 and a housing upon visual inspection after installation of the breather assembly 400 to the housing, rather than necessitating uninstalling the assembly body 410 from the housing to make such a determination. Other advantages will also be appreciated.

Returning to FIGS. 1 and 2, the breather assembly 100 has an assembly opening 111 and an environmental opening 112. The assembly opening 111 is generally configured for direct fluid communication with an interior of a housing 200, and the environmental opening 112 is generally configured to direct fluid communication with the outside environment 14. The assembly body 110 defines an airflow pathway 12 between the assembly opening 111 and the outside environment through the environmental opening 112. When coupled to a housing 200, the assembly body 110 defines an airflow pathway 12 between the interior 232 and the outside environment 14. In some embodiments, the airflow pathway 12 is configured to allow constant gaseous communication between the interior 232 and the outside environment 14. In some embodiments, the airflow pathway 12 is configured to allow selective gaseous communication between the enclosure and the outside environment 14. In some implementations, the interior 232 is configured to be isolated from the outside environment 14 except through the airflow pathway 12.

The breather assembly 100 has a conductive shield 160 coupled to the assembly body 110. The conductive shield is disposed across the assembly opening 111. The conductive shield 160 is generally electrically conductive. As such, the conductive shield 160 is constructed of an electrically conductive material. The conductive shield can be constructed of a variety of materials including metals, carbons, ceramics, cement, polymers, hybrids and composites. In some embodiments, the conductive shield can be constructed of metals such as stainless steel, silver, copper, aluminum, gold, zinc, nickel, brass, bronze, iron, platinum, steel, lead, or any one or more combination thereof. In examples, the conductive shield is constructed of stainless steel. In some embodiment the conductive shield 160 is partially or wholly constructed of a metal such as stainless steel. In other embodiments, the conductive shield 160 is constructed of a relatively conductive non-metal such as graphite. In some such examples, the conductive shield 160 can also be constructed of a polymeric material.

The conductive shield 160 is generally configured to be in conductive communication with the housing 200. Such a configuration may advantageously result in a Faraday cage to obstruct electromagnetic interference. In some embodiments, the conductive shield 160 is configured to be in direct contact with the housing 200. In some embodiments, the conductive shield 160 is configured to be in indirect, but still conductive contact, with the housing through an intermediate component that is also constructed of a conductive material. In some embodiments, the conductive shield 160 is configured to be compressibly received between the assembly body 110 and the housing 200 when the coupling structure 116 is coupled to the housing 200. In various embodiments, coupling the coupling structure 116 to the housing 200 positions the conductive shield 160 in conductive communication with the housing 200. The conductive shield 160 generally defines one or more conductive contact regions 166 configured to make conductive contact with the housing 200 around the housing opening 210 when the breather assembly 100 is coupled to the housing 200.

The conductive shield 160 generally extends across the airflow pathway 12 and has at least one opening 162 defining a portion of the airflow pathway 12. The conductive shield 160 is generally configured to facilitate airflow along the airflow pathway 12 and create an obstruction to the passage of contaminants, which can include sparks in implementations where components within the housing 200 can generate sparks. In various examples, the conductive shield 160 can reduce the likelihood that contaminants reach various components of the breather assembly 100. In the current example, the conductive shield 160 defines a plurality of openings 162 spaced laterally across the airflow pathway. In the current example, the plurality of openings 162 includes one or more circumferential openings 168 between the outer perimeter of the conductive shield 160 and the assembly body 110. In some embodiments, the plurality of openings 162 is only defined by the one or more circumferential openings 168 and lacks openings within the outer perimetric boundary of the conductive shield 160.

Each of the plurality of openings 162 are generally sized to facilitate the establishment of a Faraday cage with a housing 200 to which the barrier vent 100 is configured to be coupled. If an opening of the plurality of openings 162 is too large, then a Faraday cage may not be established. As such, each of the plurality of openings 162 has a maximum cross-dimension d, such as a diameter or diagonal measurement, that can be less that 15 mm. In some embodiments, the maximum cross-dimension d is less than 14 mm, 13 mm, 12 mm, or 10 mm. In some examples, the maximum cross-dimension d is about 8.5 mm. The conductive shield 160 may have any suitable number of openings 162, each of which may have any suitable opening shape. Samples of suitable axial cross-sectional shapes of the opening 162 include rectangles, circles, polygons, and irregular shapes.

In the current example, the conductive shield 160 is positioned towards the second end 104 of the assembly body 110. As discussed above, the breather assembly 100 is configured to conductively couple the conductive shield 160 to the housing 200 when the coupling structure 116 is coupled to the housing 200. The conductive shield 160 can be coupled to the assembly body 110 through a variety of approaches and combinations of approaches. In some embodiments, the conductive shield 160 is fastened to the housing 200. In examples, the conductive shield 160 is fastened to the assembly body 110 through the use of fasteners, adhesives, welds, and the like. In some embodiments, the conductive shield 160 is fastened to the assembly body 110 through a structure that resists melting under high temperatures. Such a configuration may advantageously maintain the conductive shield 160 over the housing opening 200 to obstruct debris in the event of a high temperature event within the housing 200.

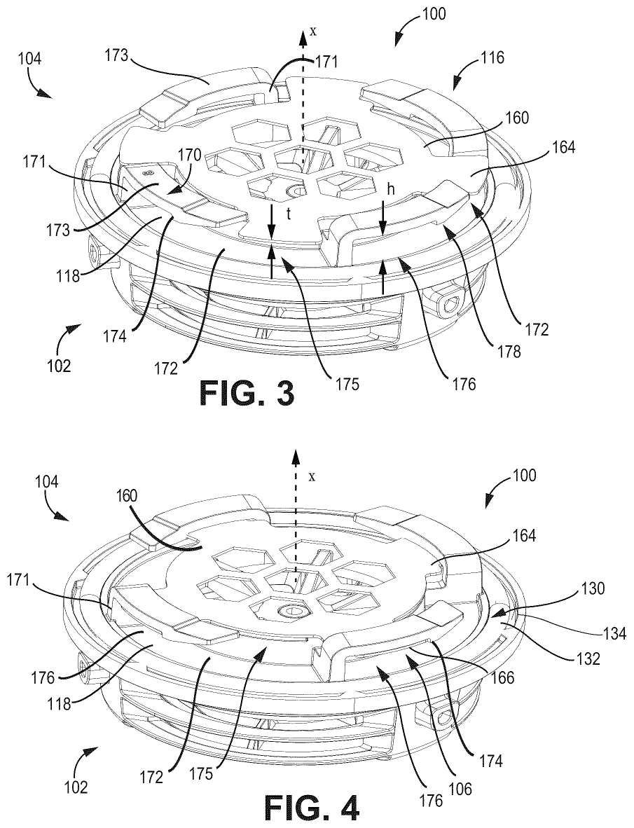

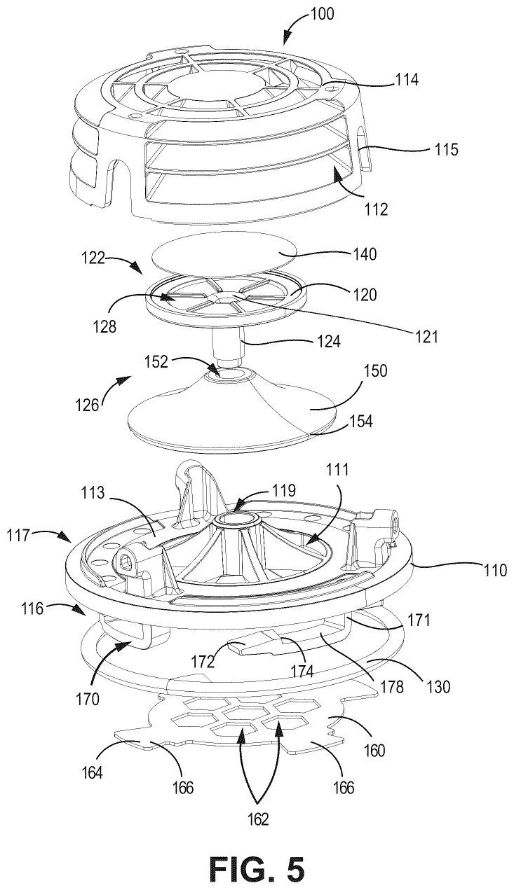

A specific example of coupling the conductive shield 160 to the breather assembly 100 will now be described with reference to the currently depicted embodiments with reference to FIGS. 2-5, wherein FIG. 3 depicts the conductive shield 160 in an uninstalled position and FIGS. 2 and 4 depict the conductive shield 160 in an installed position. FIG. 5 depicts an exploded view of the breather assembly 100. In this example, the coupling structure 116 is a bayonet connector. While the bayonet connector can have a variety of different configurations, in the current configuration the bayonet connector has a plurality of legs 170 that extend axially outward and partially circumferentially around a central axis x of the breather assembly 100. In particular, each of the plurality of legs 170 has an axial extension 171 extending axially outward from a surface 118 of the assembly body 110, and a partial circumferential extension 173 extending partially circumferentially around the central axis x of the breather assembly 100. As such, each leg 170 defines a partial circumferential channel 178 between the surface 118 of the assembly body 110 and the partial circumferential extension 173. Each circumferential channel 178 similarly extends partially circumferentially around the central axis x of the breather assembly 100.

Each partial circumferential channel 178 has an open end 172 and a closed end 176. The open end 172 and the closed end 176 are separated by an axially extending retaining ridge 174 defined by the partial circumferential extension 173 of the leg 170. In various embodiments, each partial circumferential channel 178 is configured to receive a mating bayonet connecting feature defined by the housing (200, FIGS. 1-2), such as a radial tab (not visible) extending inwardly relative to the housing opening 210.

In various embodiments, the conductive shield 160 has corresponding features that are coupled to the assembly body 110. In the current example, the conductive shield 160 is retained by the coupling structure 116. In some embodiments, the conductive shield 160 and the coupling structure 116 form an interference fit. In some embodiments, the conductive shield 160 and the coupling structure 116 are coupled through a fastener, an adhesive or a weld. In this particular example, the conductive shield 160 has a plurality of radial outwardly extending tabs 164 (particularly visible in FIG. 3) that are each configured to be received by a corresponding partial circumferential channel 178. More particularly, each of the radially extending tabs 164 are configured to be received by a closed end 176 of a corresponding partial circumferential channel 178. The conductive shield 160 may have any suitable number of radially extending tabs 164. Generally there is an equal number of radially extending tabs 164 as there are partial circumferential channels 178.

In some embodiments, each radially extending tab 164 is received by the closed end 176 between the retaining ridge 174 and the axial extension 171 of the leg 170. In some embodiments, each radially extending tab 164 is retained via an interference fit between the retaining ridge 174 and the axial extension 171 of the leg 170. In some other embodiments, at least one radially extending tab 164 is retained via a fastening mechanism to the closed end 176, such as with a fastener, an adhesive, a weld, or the like.

The assembly body 110 can be a plastic component that is formed through, for example, a molding operation such as an injection molding operation and the conductive shield 160 can be constructed of a different material such as, for example, a metal that can be formed through a machining or molding operation that would be separate from the operation used to form the assembly body. As such, the assembly body 110 and the conductive shield 160 are generally coupled after formation of each respective component. As discussed above, there are a variety of configurations through which the conductive shield 160 and the assembly body 110 can be coupled.

In the current example consistent with FIGS. 3 and 4, the conductive shield 160 is coupled to the bayonet connector such that each radial tab 164 is inserted in the axial direction between adjacent partial circumferential channels 118, which is shown in FIG. 3. From that position, the conductive shield 160 is rotated to translate each radial tab circumferentially through the open end 172 of a corresponding partial circumferential channel 118 into the closed end 176 of that channel 118, which is depicted in FIG. 4. In some embodiments, the open end 172 is tapered axially inward towards the closed end. Such a configuration may advantageously facilitate translation of each radial tab 164 into a corresponding partial circumferential channel 178.

In some embodiments, each of the plurality of partial circumferential channels 178 define a circumferential clearance 175 from an adjacent channel. The circumferential clearance 175 is sized to receive one of a plurality of radially extending tabs 164. The circumferential clearance 175 need not necessarily be larger than a corresponding radially extending tab 164, however, because there may be an interference fit between a radially extending tab 164 and the adjacent partial circumferential channels forming the circumferential clearance 175. As such, inserting the tab 164 in the axial direction into the circumferential clearance 175 may include flexing one or any of the tab 164 and the adjacent legs 170 to accommodate the axial translation of the tab 164.

In some embodiments, the plurality of partial circumferential channels 178 are circumferentially aligned. In some embodiments, the plurality of partial circumferential channels 178 are symmetrical relative to the central axis. In some embodiments, each of the partial circumferential channels 178 are equally spaced around the assembly body 110. Such configurations may advantageously accommodate orientation-independent coupling of the conductive shield 160 to the assembly body 110 and coupling of the assembly 100 to a housing.

In examples, the assembly body 110 and the conductive shield 160 define a housing clearance 106 (FIG. 4) that is configured to receive a sidewall of a housing 200 (such as depicted in FIGS. 1 and 2) when the breather assembly 100 is installed on the housing 200. The conductive contact region 166 defines a portion of the housing clearance 106. In the current example, an opposing surface 118 of the assembly body 110 defines a portion of the housing clearance 106. In some embodiments, each radially extending tab 164 has a thickness t in the axial direction that is less than an axial height h of the closed end 176 to accommodate the thickness of a sidewall of a housing 200 (notated in FIG. 3). Upon installation of the vent assembly 100 onto a housing, the conductive shield 160 is configured to be sandwiched between the leg 170 of the bayonet connector and an inner surface 202 of the housing 200 (see FIG. 2), such that the inner surface 202 of the housing 200 is in conductive contact with the conductive contact region 166.

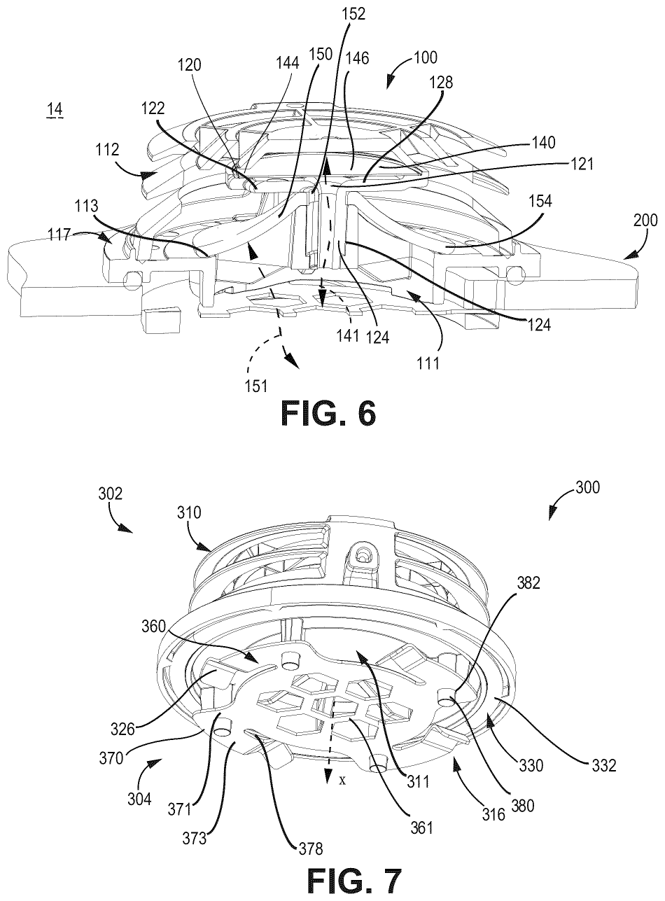

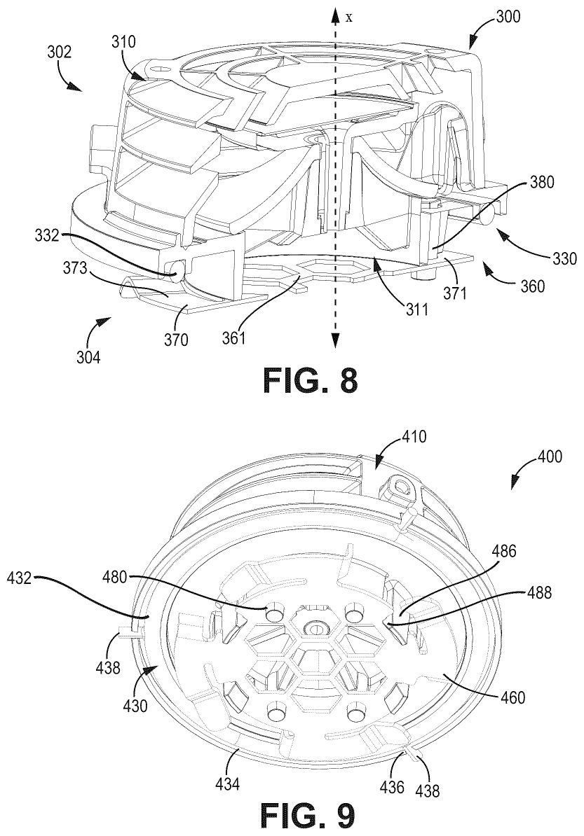

Various designs consistent with the breather assemblies 100 disclosed herein may advantageously facilitate the installation of both an assembly body 110 and a conductive shield 160 from the outside of a housing 200 without access to the inside of the housing 200, which may advantageously simplify the installation process. FIGS. 7 and 8 depict another example of a breather assembly 300 consistent with the present technology. The assembly 300 generally has components that are consistent with components discussed above with reference to FIGS. 1-6. Descriptions of components already described above should be understood to apply to the present figure, except where contradictory to the current description or figures.

The breather assembly 300 is generally configured to be coupled to a housing. The breather assembly 300 has a coupling structure 316 configured to be coupled to the housing. The breather assembly 300 has an assembly body 310 and a conductive shield 360. In the current example, a portion of the coupling structure 316 is defined by the assembly body 310 and a portion of the coupling structure 316 is defined by the conductive shield 360. The coupling structure 316 includes a bayonet connector 326. In the current example, the bayonet connector 326 is defined by the conductive shield 360. Other types of connection structures are possible however, such as those discussed above with reference to FIGS. 1-5.

The bayonet connector 326 is configured to be received by a bayonet receptacle of a housing. The bayonet connector 326 is generally configured to bring the conductive shield 360 and a housing in direct, conductive contact. The bayonet connector 326 can have a variety of different configurations that are generally known in the art and is not particularly limited. However, in the current example, the bayonet connector 326 has a plurality of legs 370 that extend radially outward and partially circumferentially around a central axis x of the breather assembly 300. In particular, each of the plurality of legs 370 has a radial extension 371 extending radially outward from a central region of the conductive shield 360, and a partial circumferential extension 373 extending partially circumferentially around the central axis x of the breather assembly 300. As such, each leg 370 defines a partial circumferential channel 378 between the central region of the conductive shield 360 and the partial circumferential extension 373. Each circumferential channel 378 similarly extends partially circumferentially around the central axis x of the breather assembly 300.

The coupling structure 316 also includes a sealing surface 330 that is configured to form a seal between the breather assembly 100 and a housing around a housing opening. As with the example discussed above, here the sealing surface 330 is defined, at least in part, by a sealing ring 332. The sealing surface 130 is defined around the bayonet connector 326.

The conductive shield 360 is disposed across an assembly opening 311 defined by the breather assembly 300. The conductive shield 360 is coupled to the assembly body 310. The conductive shield 360 is configured to be in conductive communication with a housing to which the breather assembly 300 is coupled. In the current example, the conductive shield 360 is coupled to the breather assembly 300, at least in part, through an interference fit. In particular, the assembly body 310 has a plurality of pins 380 positioned around the assembly opening 311 that each extend in the axial direction. The conductive shield 360 defines a plurality of pin openings 382. The conductive shield 360 and the pins 380 form an interference fit around the pin openings 382. In some embodiments, an adhesive, weld, or other adherence is formed between the pins 380 and the conductive shield 360.

Other configurations and combinations of configurations are also contemplated. See, for example, the example breather assembly of FIG. 9 which depicts a combination of pins 480 and pin openings 482 as discussed above, but further includes a plurality of cantilever snap fit legs 486 extending axially from the assembly body 410. The cantilever snap fit legs 486 are configured to exert a radially inward force against an outer perimetric surface of the conductive shield 460 to help retain the position of the conductive shield 360 relative to the assembly body 410. In the current example, the cantilever snap fit legs 486 each have a retaining lip 488 that is axially outward from a lateral surface of the conductive shield 360 to maintain the axial position of the conductive shield 460 relative to the assembly body 410. It will be appreciated that in some embodiments the pins 480 and corresponding pin openings 482 can be omitted. Further, other features can also be used to couple a conductive shield to an assembly body.

It is noted that the breather components of breather assemblies consistent with the technology disclosed herein is not particularly limited in various implementations of the present technology. FIG. 5 is an exploded view of an example breather assembly 100 consistent with previously described examples, with specific breather components that will now be described. FIG. 6 is a cross-sectional perspective view of the breather assembly of FIG. 5 and can be referenced with the current description. Descriptions of components already described above should be understood to apply to the present figures, except where contradictory to the current description or figures.

The breather assembly 100 has an assembly body 110, a conductive shield 160 coupled to the assembly body 110 and breather components including a vent 140 and a valve 150. In some embodiments one of the vent 140 and the valve 150 can be omitted. The assembly body 110 is generally configured to house the breather components.

The assembly body 110 generally has features already described herein. In the current example, the assembly body 110 has an assembly sidewall 115 extending in the axial direction around the central axis x and an end face 114 extending laterally across a first end of the assembly sidewall 115 and a base 117 extending laterally across a second end of the assembly sidewall 115. The assembly sidewall 115, the base 117, and the end face 114 house the breather components. The assembly sidewall 115 extends axially between the base 117 and the end face 114. In the current example the assembly sidewall 115 and the end face 114 are integrated in a single component that is coupled to the base, but in other embodiments, the assembly sidewall and the end face can be separate components.

The airflow pathway 12 defined by the assembly body 110 has a vent airflow pathway 141 and a valve airflow pathway 151 that is functionally parallel with the vent airflow pathway 142 (best visible in FIG. 6). The breather assembly 100 has a valve 150 disposed in the assembly body 110 that selectively obstructs the valve airflow pathway 151. The valve 150 selectively obstructs a valve airflow pathway 151 between the assembly opening 111 and the environmental opening 112. The valve 150 is generally configured to allow gases from inside the housing 200 to escape to the outside environment 14 when the environment inside the housing 200 undergoes a relative pressure spike. Upon a pressure event inside the housing 200 that reaches a first threshold pressure, the valve 150 is configured to open. In some embodiments the valve 150 opens irreversibly. In some embodiments the valve 150 opens reversibly, meaning that the valve 150 returns to a closed position once the pressure inside the housing lowers to a second threshold pressure.

In the current example, the valve 150 is an elastomeric valve having a sealing lip 154. The assembly body 110 defines a valve sealing surface 113 that receives the sealing lip 154. The valve sealing surface 113 is defined circumferentially around a central axis of the breather assembly 100. Upon a relatively high-pressure event within the housing 200, the sealing lip 154 is temporarily displaced from the valve sealing surface 113 to release pressure along the valve airflow pathway 151. In some embodiments the valve can be omitted. It should be appreciated that the specific valve design is not particularly limited and various alternative valve designs can be used with breather assemblies consistent with the technology disclosed herein.

In the current example, the breather assembly 100 has a vent 140 disposed in the assembly body 110. The vent 140 allows passive airflow along the vent airflow pathway 141 between the first end 102 and the second end 104 of the assembly body 110 under normal pressure conditions. In some embodiments the vent 140 is configured to prevent liquids and particulates from passing therethrough. The vent 140 can be a variety of materials and combinations of materials. Upon a high-pressure event inside the housing 200 however, as discussed above, the breather assembly 100 is configured to allow gases to escape the housing 200 by bypassing the vent airflow pathway 141 and the vent 140.

The vent 140 can be constructed of a variety of different materials and combinations of materials. In some embodiments the vent 140 is a metal foil. The vent 140 can be an elastomeric material such as latex. In various embodiments the vent 140 incorporates a breathable membrane. The breathable membrane can incorporate expanded polytetrafluorethylene (ePTFE), sintered polytetrafluorethylene (PTFE), or other types of breathable membranes. The breathable membrane is generally porous to accommodate airflow. The breathable membrane can have a Frazier Permeability of 0.035 to 8.0 ft/min at 0.5 inches of water, and more particularly 0.035 to 3.0 ft/min at 0.5 inches of water.

The vent 140 can be a laminate or composite that includes a breathable membrane. For example, the vent 140 can be a breathable membrane laminated to a woven or non-woven support layer. In another example, the vent 140 can be a breathable membrane having a coating. In some other embodiments, the vent 140 can be a breathable membrane alone, without another layer. In some embodiments, the vent 140 is a woven fabric or a non-woven fabric. The vent 140 can be constructed of hydrophobic material, or the vent 140 can be treated to exhibit hydrophobic properties. In one example, the vent 140 is a hydrophobic woven or non-woven fabric. In some embodiments the vent 140 has a support ring to support the periphery of the vent 140 that is coupled to the vent mounting surface 120.

The breather assembly 100 has a vent mounting surface 120 on which the vent 140 is mounted. The vent 140 has a perimeter region 144 that bonded to the vent mounting surface 120 and an unbonded region 146 central to the perimeter region 144. The vent mounting surface 120 surrounds a vent opening 121 that defines the vent airflow pathway 141. The vent mounting surface 120 is defined by the assembly body 110. In examples, the assembly has a vent stand 122 that defines the vent mounting surface 120. The vent stand 122 has a stem portion 124 extending axially outward from the vent mounting surface 120. The vent mounting surface 120 is positioned radially outward from the stem portion 124. The vent airflow pathway 141 extends through the stem portion 124 and the vent mounting surface 120 such that the stem portion 124 and the vent mounting surface 120 surround the vent airflow pathway 141. In the current example, the valve airflow pathway 151 surrounds the vent stand 122. In various embodiments, the vent stand 122 has a lateral extension 128. The lateral extension 128 extends laterally outward from the stem portion 124. The vent mounting surface 120 is defined by an outer region of the lateral extension 128. A recessed surface 129 is defined centrally to the vent mounting surface 120. The recessed surface 129 is spaced from the vent 150 in the axial direction. Such a configuration exposes the unbonded surface area of the vent 150, which may advantageously increase the surface area of the vent 150 available for airflow.

In various implementations, the unbonded region 146 of the vent 140 extends beyond the vent airflow pathway 141 defined in the stem portion 124 in the lateral direction. In various implementations, the unbonded region 146 of the vent 140 extends beyond the stem portion 124 in the lateral direction. Such a configuration may advantageously provide a relative increase in the airflow capacity through the vent 140 by relatively increasing the available surface area of the vent 140 compared to a vent having a relatively smaller unbonded region.

The vent stand 122 is a separate component that is coupled to a base 117 of the assembly body 110, but in some other embodiments the vent stand 122 integral with the assembly body 110 to form a single, unitary component. The stem portion 124 is coupled to the base 117. In some embodiments the stem portion 124 and the assembly body 110 form an interference fit, such as in this example where the base 117 defines a stem opening 119 that receives and engages the stem portion 124. In the current example, the stem portion 124 extends through an opening 152 defined by the valve 150.

In various embodiments, the valve 150 is coupled to the vent stand 122. The valve 150 extends radially outward from the stem portion 124. In particular, the valve 150 has an inner perimeter defining the valve opening 152, and the valve 150 extends from the inner perimeter to the sealing lip 154 defined by the outer perimeter. The valve 150 extends to the valve sealing surface 113 defined by the assembly body 110. In various embodiments, the valve sealing surface 113 is positioned radially outward from the stem portion 124. In some embodiments the valve 150 is compressibly received between the assembly body 110 and the lateral extension 128. For example, a portion of the valve 150 defining the inner perimeter can be compressibly received between the assembly body 110 and the lateral extension 128. Such a configuration may be used, for example, where the stem portion 124 and the assembly body 110 form an interference fit.

The vent 140 is coupled to the vent mounting surface 120 across the vent airflow pathway 141. In the current example, the vent 140 forms a circular disk, although the vent 140 can have other shapes as well. The vent 140 can be coupled to the vent mounting surface 120 with adhesive to form a seal between the vent 140 and the vent mounting surface 120. The vent 140 can be coupled to the vent mounting surface 120 with an adhesive or through other approaches such as heat welding. In some embodiments the assembly body 110 can be over-molded to the vent 140. In some embodiments the vent and its corresponding structural components such as the vent stand can be omitted. Furthermore, it should be appreciated that the specific vent design is not particularly limited and various alternative vent designs can be used with breather assemblies consistent with the technology disclosed herein.

### EXEMPLARY ASPECTS

Aspect 1. A breather assembly comprising:
an assembly body having a coupling structure configured to be coupled to a housing, an assembly opening, and an environmental opening, the assembly body configured to define an airflow pathway between the assembly opening and an outside environment through the environmental opening; and
a conductive shield coupled to the assembly body and disposed across the assembly opening, the conductive shield defining a portion of the airflow pathway, wherein the conductive shield is configured to be in conductive communication with the housing in response to the coupling structure being coupled to the housing.

Aspect 2. The breather assembly of any one of Aspects 1 and 3-15, wherein the assembly body is constructed of plastic.

Aspect 3. The breather assembly of any one of Aspects 1-2 and 4-15, wherein the coupling structure comprises a bayonet connector.

Aspect 4. The breather assembly of any one of Aspects 1-3 and 5-15, wherein the bayonet connector is defined by the conductive shield.

Aspect 5. The breather assembly of any one of Aspects 1-4 and 6-15, wherein the bayonet connector is defined by the assembly body.

Aspect 6. The breather assembly of any one of Aspects 1-5 and 7-15, wherein the conductive shield and the bayonet connector define an interference fit.

Aspect 7. The breather assembly of any one of Aspects 1-6 and 8-15, wherein the bayonet connector defines a plurality of partial circumferential channels each having an open end and a closed end, wherein the open end and the closed end are separated by an axially extending retaining ridge.

Aspect 8. The breather assembly of any one of Aspects 1-7 and 9-15, wherein the plurality of partial circumferential channels are circumferentially aligned.

Aspect 9. The breather assembly of any one of Aspects 1-8 and 10-15, wherein the open end is tapered axially inward towards the closed end.

Aspect 10. The breather assembly of any one of Aspects 1-9 and 11-15, wherein the conductive shield comprises a plurality of radially extending tabs, wherein each radially extending tab is received by a closed end.

Aspect 11. The breather assembly of any one of Aspects 1-10 and 12-15, wherein each of the plurality of partial circumferential channels define a circumferential clearance from an adjacent channel that is sized to receive one of the plurality of radially extending tabs.

Aspect 12. The breather assembly of any one of Aspects 1-11 and 13-15, wherein each radially extending tab has a thickness that is less than an axial height of the closed end.

Aspect 13. The breather assembly of any one of Aspects 1-12 and 14-15, wherein the conductive shield is stainless steel.

Aspect 14. The breather assembly of any one of Aspects 1-13 and 15, further comprising a valve disposed in the assembly body, wherein the valve selectively obstructs the airflow pathway between the assembly opening and the environmental opening.

Aspect 15. The breather assembly of any one of Aspects 1-14, wherein the conductive shield defines a plurality of openings across the airflow pathway.

Aspect 16. A method of making a breather assembly comprising:
forming an assembly body having a coupling structure configured to be coupled to a housing, an assembly opening, and an environmental opening, the assembly body configured to define an airflow pathway between the assembly opening and an outside environment through the environmental opening; and
coupling a conductive shield to the assembly body across the assembly opening, the conductive shield defining a portion of the airflow pathway, and the conductive shield is configured to be in conductive communication with the housing when the coupling structure is coupled to the housing.

Aspect 17. The method of any one of Aspects 16 and 18-28, wherein the assembly body is constructed of plastic.

Aspect 18. The method of any one of Aspects 16-17 and 19-28, wherein the coupling structure comprises a bayonet connector.

Aspect 19. The method of any one of Aspects 16-18 and 20-28, wherein the bayonet connector is defined by the assembly body.

Aspect 20. The method of any one of Aspects 16-19 and 21-28, wherein the bayonet connector is defined by the conductive shield.

Aspect 21. The method of any one of Aspects 16-20 and 22-28, wherein the conductive shield and the bayonet connector define an interference fit.

Aspect 22. The method of any one of Aspects 16-21 and 23-28, wherein coupling the conductive shield to the bayonet connector comprises:
inserting each of a plurality of radially extending tabs defined by the conductive shield between each of a plurality of partial circumferential channels defined by the bayonet connector; and rotating the conductive shield relative to the bayonet connector to translate each radially extending tab from an open end of a corresponding partial circumferential channel to a closed end of the corresponding partial circumferential channel, wherein the open end and the closed end are separated by an axially extending retaining ridge.

Aspect 23. The method of any one of Aspects 16-22 and 24-28, wherein the plurality of partial circumferential channels are circumferentially aligned.

Aspect 24. The method of any one of Aspects 16-23 and 25-28, wherein the open end is tapered axially inward towards the closed end.

Aspect 25. The method of any one of Aspects 16-24 and 26-28, wherein each radially extending tab has a thickness that is less than an axial height of the closed end.

Aspect 26. The method of any one of Aspects 16-25 and 27-28, wherein the conductive shield is stainless steel.

Aspect 27. The method of any one of Aspects 16-26 and 28, further comprising coupling a valve to the assembly body to selectively obstruct the airflow pathway between the assembly opening and the environmental opening.

Aspect 28. The method of any one of Aspects 16-27, wherein the conductive shield defines a plurality of openings across the airflow pathway.

It should also be noted that, as used in this specification and the appended claims, the phrase “configured” describes a system, apparatus, or other structure that is constructed to perform a particular task or adopt a particular configuration. The word “configured” can be used interchangeably with similar words such as “arranged”, “constructed”, “manufactured”, and the like.

All publications and patent applications in this specification are indicative of the level of ordinary skill in the art to which this technology pertains. All publications and patent applications are herein incorporated by reference to the same extent as if each individual publication or patent application was specifically and individually indicated by reference. In the event that any inconsistency exists between the disclosure of the present application and the disclosure(s) of any document incorporated herein by reference, the disclosure of the present application shall govern.

This application is intended to cover adaptations or variations of the present subject matter. It is to be understood that the above description is intended to be illustrative, and not restrictive, and the claims are not limited to the illustrative embodiments as set forth herein.

What is claimed is:

1. A breather assembly comprising:
an assembly body having a coupling structure configured to be coupled to a housing, an assembly opening, and an environmental opening, the assembly body configured to define an airflow pathway between the assembly opening and an outside environment through the environmental opening; and
a conductive shield coupled to the assembly body and disposed across the assembly opening, the conductive shield defining a portion of the airflow pathway, wherein the conductive shield is configured to be in conductive communication with the housing in response to the coupling structure being coupled to the housing.

2. The breather assembly of claim 1, wherein the assembly body is constructed of plastic.

3. The breather assembly of claim 1, wherein the coupling structure comprises a bayonet connector.

4. The breather assembly of claim 3, wherein the bayonet connector is defined by the conductive shield.

5. The breather assembly of claim 3, wherein the bayonet connector is defined by the assembly body.

6. The breather assembly of claim 3, wherein the conductive shield and the bayonet connector define an interference fit.

7. The breather assembly of claim 3, wherein the bayonet connector defines a plurality of partial circumferential channels each having an open end and a closed end, wherein the open end and the closed end are separated by an axially extending retaining ridge.

8. The breather assembly of claim 7, wherein the plurality of partial circumferential channels are circumferentially aligned.

9. The breather assembly of claim 7, wherein the open end is tapered axially inward towards the closed end.

10. The breather assembly of claim 8, wherein the conductive shield comprises a plurality of radially extending tabs, wherein each radially extending tab is received by a closed end.

11. The breather assembly of claim 10, wherein each of the plurality of partial circumferential channels define a circumferential clearance from an adjacent channel that is sized to receive one of the plurality of radially extending tabs.

12. The breather assembly of claim 10, wherein each radially extending tab has a thickness that is less than an axial height of the closed end.

13. The breather assembly of claim 1, wherein the conductive shield is stainless steel.

14. The breather assembly of claim 1, further comprising a valve disposed in the assembly body, wherein the valve selectively obstructs the airflow pathway between the assembly opening and the environmental opening.

15. The breather assembly of claim 1, wherein the conductive shield defines a plurality of openings across the airflow pathway.

16. A method of making a breather assembly comprising:
forming an assembly body having a coupling structure configured to be coupled to a housing, an assembly opening, and an environmental opening, the assembly body configured to define an airflow pathway between the assembly opening and an outside environment through the environmental opening; and
coupling a conductive shield to the assembly body across the assembly opening, the conductive shield defining a portion of the airflow pathway, and the conductive shield is configured to be in conductive communication with the housing when the coupling structure is coupled to the housing.

17. The method of claim 16, wherein the coupling structure comprises a bayonet connector.

18. The method of claim 17, wherein the bayonet connector is defined by the conductive shield.

19. The method of claim 17, wherein the conductive shield and the bayonet connector define an interference fit.

20. The method of claim 17, wherein coupling the conductive shield to the bayonet connector comprises:
inserting each of a plurality of radially extending tabs defined by the conductive shield between each of a plurality of partial circumferential channels defined by the bayonet connector; and rotating the conductive shield relative to the bayonet connector to translate each radially extending tab from an open end of a corresponding partial circumferential channel to a closed end of the corresponding partial circumferential channel, wherein the open end and the closed end are separated by an axially extending retaining ridge.
